(19) United States
(12) Patent Application Publication
(10) Pub. No.: US 2014/0184346 A1
(43) Pub. Date: Jul. 3, 2014

(54) Voltage-Controlled Oscillator Circuit Structure

(71) Applicant: Industrial Technology Research Institute, Hsinchu (TW)

(72) Inventors: Sih-Han LI, New Taipei City (TW); Chih-Sheng LIN, Tainan City (TW); Hsin-Chi LAI, Taichung City (TW); Keng-Li SU, Zhubei City (TW)

(21) Appl. No.: 13/915,466

(22) Filed: Jun. 11, 2013

(30) Foreign Application Priority Data
Dec. 28, 2012 (TW) 101151125

(51) Int. Cl. H03B 5/12

(52) U.S. Cl. CPC H03B 5/1243
USPC 331/115; 331/117 FE

(57) ABSTRACT

A voltage-controlled oscillator (VCO) is provided. The VCO includes an oscillator unit disposed on a substrate, and a varactor unit. The varactor unit is coupled to the oscillator unit to form a VCO loop. The varactor unit includes a varactor and at least one control terminal. The varactor is disposed in the substrate, and includes at least two through-silicon via (TSV) structures. The at least one control terminal renders the varactor unit to be biased to change a capacitance value of the varactor.

This application claims the benefit of Taiwan application Serial No. 101151125, filed Dec. 28, 2012, the disclosure of which is incorporated by reference herein in its entirety.

### TECHNICAL FIELD

The disclosure relates to a voltage-controlled oscillator (VCO) circuit structure, and to a VCO having a varactor unit formed based on through-silicon via (TSV) structures and associated circuit.

### BACKGROUND

A conventional wireless transceiver involves two different paths—a reception path and a transmission path. For a reception signal, after receiving the signal at a front-end circuit via an antenna, the signal is down-converted and demodulated by utilizing a local oscillator (LO) and a mixer. The demodulated signal is then forwarded to a back-end circuit for signal processing. For a transmission signal, a signal to be transmitted is first processed by a back-end circuit, and similarly up-converted and modulated by an LO and a mixer. The up-converted and modulated signal is then forwarded to an antenna in a transmission end circuit, and transmitted via the antenna. During the above processes, the LO is a critical component for down/up-converting and demodulating/modulating a signal, implying that an incorrect frequency of the LO may result in severe errors in signal reception and transmission. To output an accurate frequency, an LO usually implements a phase-locked loop (PLL) for generating a stable oscillation frequency.

In a PLL architecture, a voltage-controlled oscillator (VCO) is a pivotal part for generating a maximum frequency, and is thus extensively researched for enhanced characteristics in tunable frequency, phase noise performance and power consumption.

In a VCO, an output frequency of a resonant cavity of an LC is commonly adjusted by utilizing a varactor, which however occupies a sizable area on a chip in an actual design of an integrated circuit. Therefore, there is a need for a suitable design solution that provides a VCO with an appropriate output frequency range.

### SUMMARY

The disclosure is directed to a voltage-controlled oscillator (VCO) circuit structure.

According to one embodiment, a VCO is provided. The VCO includes an oscillator unit and a varactor unit. The oscillator unit is disposed on a substrate. The varactor unit and the oscillator unit are coupled to form a VCO loop. The varactor unit includes a varactor formed based on at least two through-silicon via (TSV) structures, and at least one control terminal for rendering the varactor unit to be biased or connected to a bias circuit to change a capacitance value of the varactor.

According to another embodiment, a VCO circuit is provided. The VCO circuit includes an active unit, an inductor unit and a varactor unit. The varactor unit, the inductor unit and the active unit are coupled to form a VCO loop. The varactor unit includes a varactor formed based on at least two TSV structures, and at least one control terminal for rendering the varactor unit to be biased or connected to a bias circuit to change a capacitance value of the varactor.

### BRIEF DESCRIPTION OF THE DRAWINGS

FIG. 1 is a schematic diagram of a voltage-controlled oscillator (VCO) according to an embodiment.

FIG. 2 is an equivalent circuit diagram of a VCO circuit according to an embodiment.

FIG. 3 is a top view of a VCO according to an embodiment.

FIG. 4 is a sectional view of a varactor unit according to an embodiment.

FIG. 5 is a schematic diagram of a VCO according to another embodiment.

FIG. 6 is a schematic diagram of a VCO according to another embodiment.

FIGS. 7 and 8 show a varactor unit in a VCO according to other embodiments.

FIG. 9 is a schematic diagram of an equivalent circuit of the varactor unit in FIG. 4.

FIGS. 10A and 10B are simplified circuit diagrams of FIG. 9.

FIG. 11 is a simplified circuit diagram of FIG. 9.

FIG. 12 is a schematic diagram of a varactor according to an embodiment.

FIG. 13 is a relationship diagram between a capacitance value of a varactor unit and a control voltage.

FIG. 14 is a comparison of a tunable range of a VCO for a varactor unit having single-layer and two-layer TSVs.

FIG. 15 is a schematic diagram of a varactor unit according to another embodiment.

FIG. 16 is a schematic diagram of a varactor unit according to yet another embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

FIG. 1 shows a schematic diagram of a voltage-controlled oscillator (VCO) 10 according to an embodiment of the disclosure. In the embodiment, the VCO 10 includes an oscillator unit 11 and a varactor unit 13. The VCO 10 further includes a first output end V_{O1} and a second output end V_{O2} for outputting oscillation signals. The oscillator unit 11 is disposed on a substrate 1, and is coupled to the varactor unit 13 to form a VCO loop. The varactor unit 13 includes a varactor 15 and at least one control terminal N_{c}. The varactor 15 includes at least two through-silicon via (TSV) structures, e.g., TSVs 17 and 19. The TSVs 17 and 19 are disposed in the substrate 1, and serve as a varactor through mutual electric coupling. The control terminal N_{c} renders the varactor unit 13 to be biased (e.g., represented by Vₜᵤₙₑ) or to be connected to a bias circuit to change, for example, a capacitance value of the varactor 15 in the varactor unit 13. In an alternative embodiment based on FIG. 1, the varactor unit 13 may include multiple varactors, which may disposed in the same substrate 1 or in different substrates and connected in serial and/or parallel to change the capacitance value of the varactors. Details of such variation shall be described shortly.

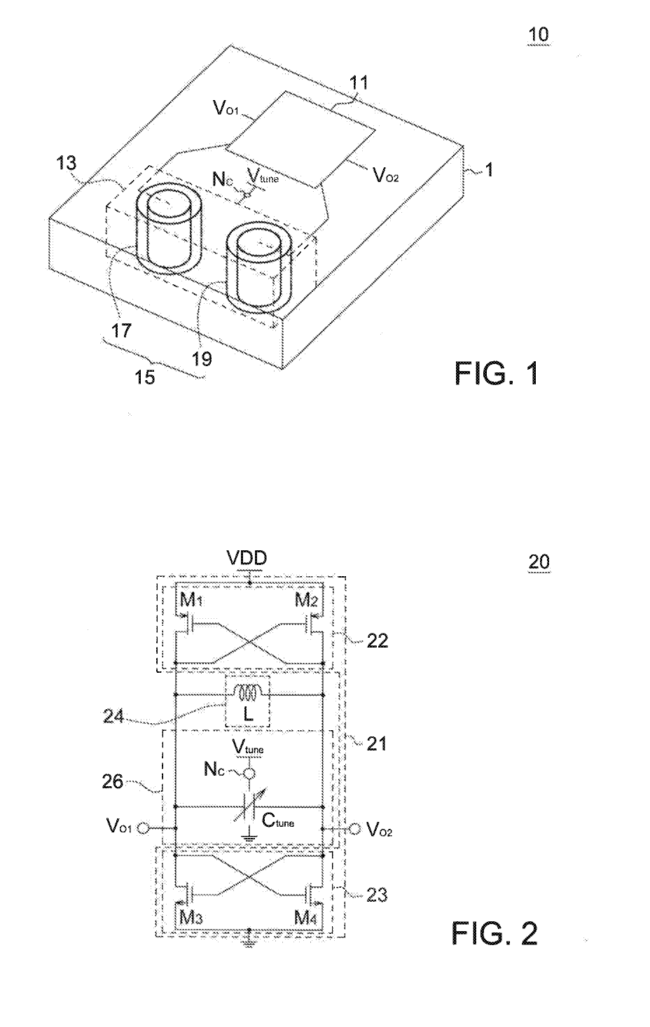

The oscillator unit 11 according to an embodiment is illustrated below with reference to FIG. 2. FIG. 2 shows an equivalent circuit diagram of a VCO circuit 20 according to an embodiment, and may be regarded as a representation in form of circuit components for the VCO 10 in FIG. 1. The VCO circuit 20 includes an active unit 21, an inductor unit 24 and a varactor unit 26. In FIG. 2, circuit component symbols in the varactor unit 26 may represent an embodiment formed by different structures of the varactor unit 13 in FIG. 1. The active unit 21 and the inductor unit 24 in FIG. 2 are an embodiment of the oscillator unit 11. For example, the active unit 21 is a circuit capable of implementing negative impedance for an oscillator to generate oscillations. For example, the active unit 21 is a circuit formed by components such as CMOS cross-coupled transistor pairs 22 and 23. The cross-coupled transistor pair 22 includes P-type transistors M₁ and M₂, and the cross-coupled transistor pair 23 includes N-type transistor M₃ and M₄. As shown in FIG. 2, the drain of the transistor M₁ is electrically connected to the gate of the transistor M₂; the drain of the transistor M₂ is electrically connected to the gate of the transistor M₁; the sources of the transistors M₁ and M₂ are electrically connected to a voltage supply VDD. Further, the drain of the transistor M₃ is electrically connected to the gate of the transistor M₄; the drain of the transistor M₄ is electrically connected to the gate of the transistor M₃; the sources of the transistors M₃ and M₄ are both connected to a ground level (or another voltage supply). Further, in the cross-coupled transistor pair 22, the drains of the transistors M₁ and M₂ are electrically coupled to two ends of the inductor unit 24 exemplified by an inductor L, respectively. In the cross-coupled transistor pair 23, the drains are also coupled to two ends of the varactor unit 26 represented by Cₜᵤₙₑ, respectively. The inductor unit 24 and the varactor unit 26 are connected in parallel. As such, the oscillator unit formed by the active unit 21 and the inductor unit 24 is coupled to the varactor unit 26 to form the VCO circuit 20.

The oscillator unit 11 is not limited to the above embodiment. In an alternative embodiment, the active unit of the oscillator unit may be implemented by other cross-coupled transistor pairs such as PMOS transistor pairs, NMOS transistor pairs or other types of transistor pairs (e.g., BJT transistor pairs). Also, the active unit may be, for example, implemented by a negative impedance circuit formed by an operation amplifier or a diode. For another example, the inductor unit 24 is a circuit formed by one or multiple inductance elements.

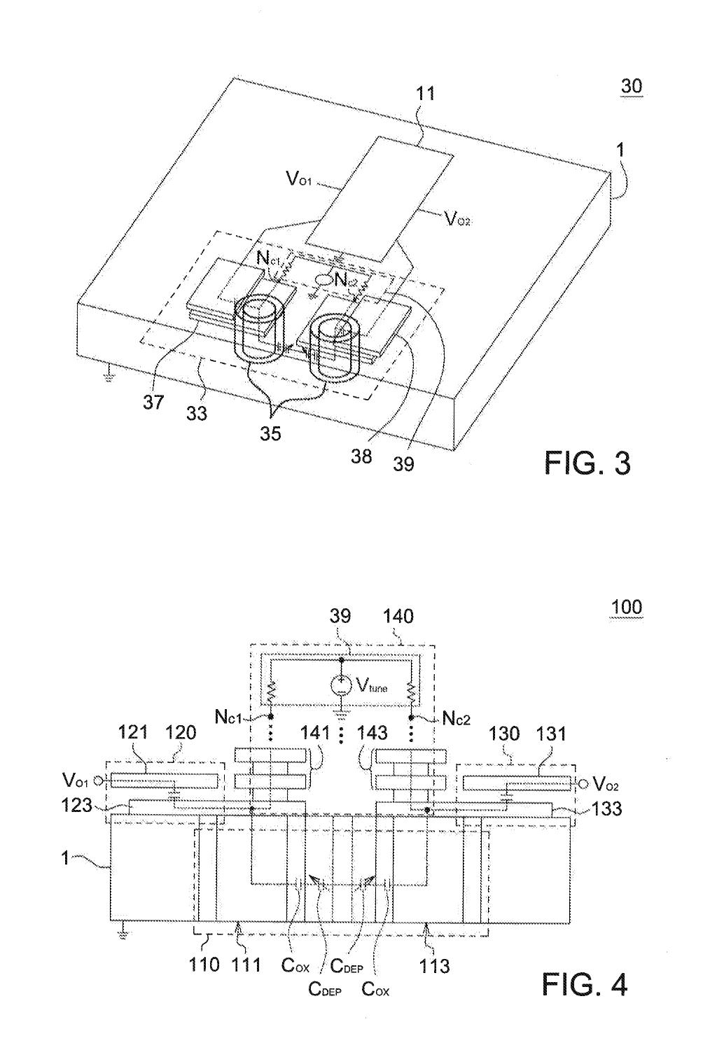

A VCO structure formed by coupling a varactor unit 33 and the oscillator unit 11 according to an embodiment is described below with reference to FIG. 3. FIG. 3 shows a top view of a VCO according to an embodiment. In FIG. 3, a VCO 30 includes an oscillator unit 11 and a varactor unit 33. For example, the oscillator unit 11 includes the active units (e.g., 21 and 22) and the inductor unit 24 in FIG. 2, or other active units. The varactor unit 33 includes a first control terminal N_{c1}, a second control terminal N_{c2}, a varactor 35, a first DC isolation device 37 and a second DC isolation device 38. The varactor 35 is coupled between the first control terminal N_{c1} and the second control terminal N_{c2}, and includes at least two TSV structures. When the varactor 35 is biased due to the first control terminal N_{c1} and the second control terminal N_{c2} or connected to a bias circuit 39 shown in FIG. 3, the capacitance value of the varactor 35 can be changed. Further, in addition to the method in the above embodiment, in a VCO according to an alternative embodiment, a bias (or a control voltage) may be provided a system circuit where the VCO 30 is located or an external circuit.

In a VCO of another embodiment, the oscillator unit 11 may include an oscillator circuit having a constant oscillation output frequency. By connecting the oscillator unit 11 to one or multiple varactor units (e.g., 13, 33 or those in following embodiments) in serial and/or parallel, an overall tunable range of the oscillation frequency of the VCO can be changed.

FIG. 4 shows a sectional view of a varactor unit according to an embodiment, and may be regarded as a sectional view of the varactor unit 33 of the embodiment in FIG. 3. In FIG. 4, a first DC isolation device 120 and a second isolation device 130 of a varactor unit 100 are disposed on the substrate 1. A varactor 110 of the varactor unit 100 is coupled between the first DC isolation device 120 and the second DC isolation device 130. The first DC isolation device 120 is coupled between a first output end V_{O1} and the varactor 110, and the second DC isolation device 130 is coupled between a second output end V_{O2} and the varactor 110.

In FIG. 4, through a bias path 140, the varactor unit 100 controls a depletion region capacitor C_{DEP} between two TSVs. Further, the substrate 1 (e.g., a silicon substrate) may also perform independent bias (e.g., connecting to ground in FIG. 4) by connecting to a predetermined voltage level, e.g., a ground level or other voltage levels. A capacitance value of the depletion region capacitor C_{DEP} is adjustable according to a change in a potential difference between the TSVs and the substrate 1.

In FIG. 4, a capacitance effect is also produced due to mutual electric coupling of the two TSVs, which may thus serve as two end points of the varactor 110. By coupling the two end points of the varactor 110 to the two DC isolation devices, the two end points of the varactor 110 may connect to signal end points (e.g., the output ends V_{O1} and V_{O2}) while preventing external signals from affecting a bias point of the varactor 110. In FIG. 4, an insulation layer capacitor (e.g., an oxidation layer capacitor) is denoted as C_{OX}.

For example, the first DC isolation device 120 includes at least two conductors 121 and 123 correspondingly disposed, so as to generate a DC isolation capacitance between the conductors 121 and 123 in the first DC isolation device 120. For example, the second DC isolation device 130 includes at least two conductors 131 and 133 correspondingly disposed, so as to generate a DC isolation capacitance between the conductors 131 and 133 in the second DC isolation device 130. The DC isolation device may be formed by coupling multiple conductors to isolate DC signals on a transmission path while allowing AC signals to pass through. The multiple conductors forming the DC isolation device may be metal in an arbitrary number of layers or conductors such as polysilicon (e.g., first and second conductive layers). Further, the conductors of the DC isolation device may be implemented by an arbitrary corresponding arrangement, such as multi-layer parallel plates, a finger or interdigital arrangement or other capacitor arrangements.

The varactor 110 includes at least one first TSV structure 111 and at least one second TSV structure 113 disposed in the substrate 1. The first TSV structure 111 is coupled to the first DC isolation device 120 and the first control terminal N_{c1}, and the second TSV structure 113 is coupled to the second DC isolation device 130 and the second control terminal N_{c2}.

The varactor unit 100 may further include at least one conductive layer 141, which is disposed on the substrate 1 and coupled between the first control terminal N_{c1} and the first TSV structure 111. The varactor unit 100 may further include at least one conductive layer 143, which is disposed on the substrate 1 and coupled between the second control terminal N_{c2} and the second TSV structure 113.

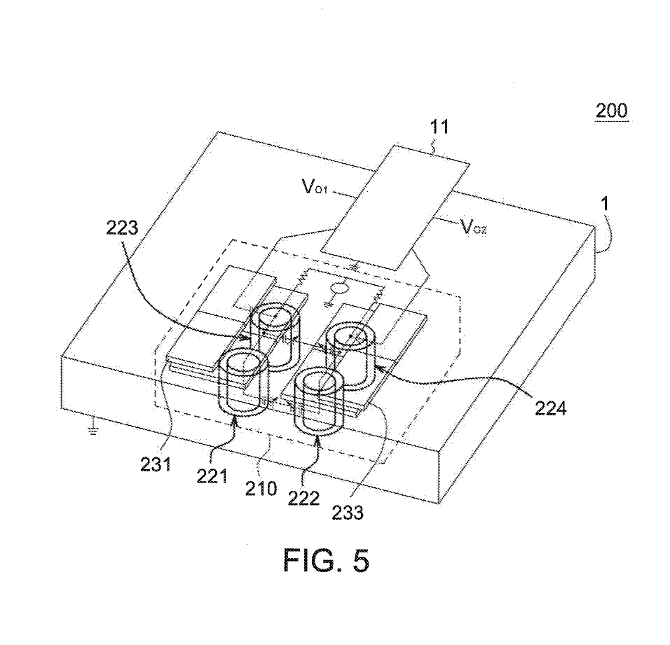

In an alternative embodiment, the varactor unit may include one or multiple varactors that are formed based on at least two TSVs and connected in series and/or parallel. FIG. 5 shows a schematic diagram of a VCO according to another embodiment. A main difference of a VCO 200 in FIG. 5 from the VCO 30 in FIG. 3 is that, a varactor of a varactor unit 210 includes two pairs of TSV structures 221 and 222, and 223 and 224, and may be regarded as formed by two varactors connected in parallel. In FIG. 5, the varactor unit 210 includes a first DC isolation device 231 and a second DC isolation device 233. The first DC isolation device 231 is coupled to the TSV structures 221 and 223, and the second DC isolation device 233 is coupled to the TSV structures 222 and 224.

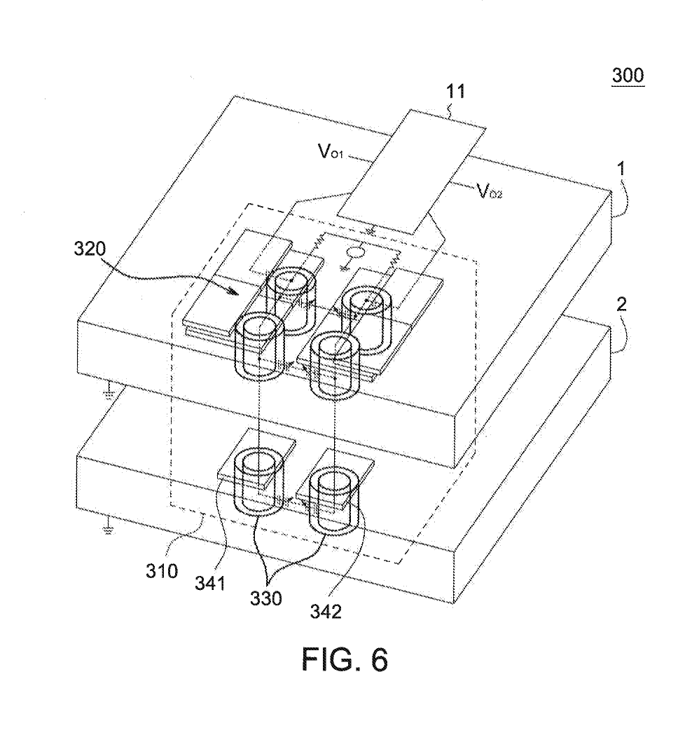

In another embodiment, multiple varactors of the varactor unit may be disposed in the same substrate or in different substrates, and may be coupled in series and/or parallel. Referring to FIG. 6 showing an embodiment, a varactor unit 310 of a VCO 300 includes a varactor 320 disposed at a first stacked layer (e.g., the substrate 1), and another varactor 330 disposed in a second stacked layer (e.g., the substrate 2). The second varactor 330 may be connected in parallel with the first varactor 320. The VCO 300 in FIG. 6 may further include connecting conductive layers 341 and 342 disposed between the first stacked layer (e.g., the substrate 1) and the second stacked layer (e.g., the substrate 2). The connecting conductive layer 341 couples a TSV structure of the first varactor 320 to one end of the second varactor 330, and the connecting conductive layer 342 couples another TSV structure of the first varactor 320 to the other end of the second varactor 330.

In the above embodiments, the first DC isolation device and the second DC isolation device of the VCO may be disposed at the same side of the substrate. In an alternative embodiment, the first DC isolation device and the second DC isolation device of the VCO may also be disposed at different sides of the substrate, thereby adapting the output end and output signals of the VCO to be suitable for various flexible designs and applications.

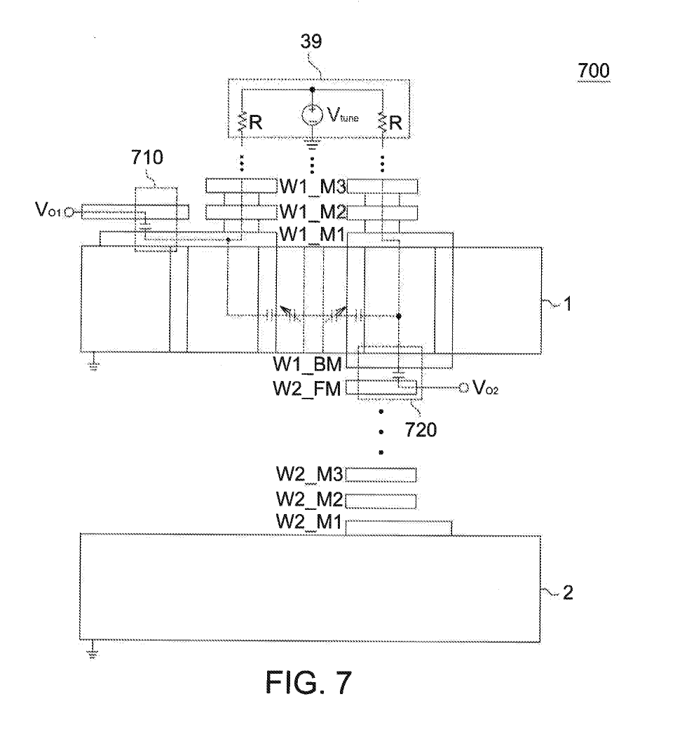

As shown in FIG. 7, first and second DC isolation devices 710 and 720 of a varactor unit 700 are respectively disposed at different sides of the substrate 1. The embodiment may also be applied to multi-layer wafers. Taking two layers of stacked wafers for example, the lower-layer metal (BM)W1_BM of an upper-layer wafer (W1) and the upper-layer metal (FM)W2_FM of a lower-layer wafer (W2) may be utilized to realize the second DC isolation device 720 corresponding to an output end (e.g., serving as the output end V_{O2} of the VCO) of the varactor unit 700, where W1_M1 (Wafer_Metal1) represents the first conductive layer of the upper-layer wafer, and similar symbols can be deduced accordingly and shall be omitted herein. Thus, two ends of the varactor unit 700 or the output ends V_{O1} and V_{O2} of the VCO can be coupled to other wafer layers via any desired wafer layer.

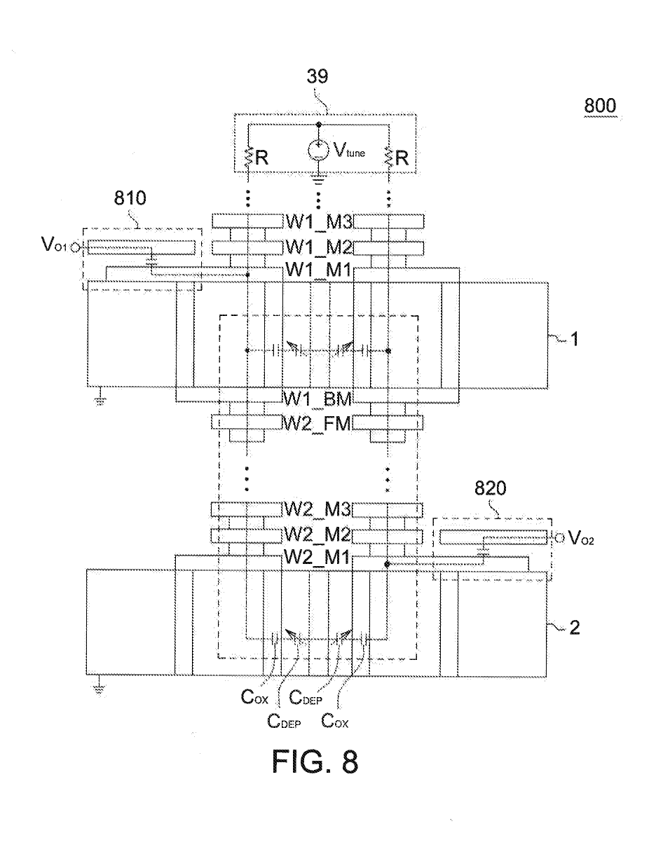

As shown in FIG. 8, in a varactor unit 800, a first DC isolation device 810 is disposed on a first stacked layer (e.g., the substrate 1), and a second DC isolation device 820 is disposed on a second stacked layer (e.g., the substrate 2). The embodiment may be applied to a parallel structure of multiple varactors formed based on multi-layer (at least two layers) TSVs. In an example of two stacked layers and performing independent bias on the varactor unit (or the TSVs) by the bias circuit 39, a greater varactor value can be obtained compared to a single-layer TSV structure. To correspond to the above coupling structure, the two ends of the varactor unit 800 or the output ends V_{O1} and V_{O2} of the VCO may also be disposed at any desired wafer layer.

An equivalent circuit and a simplified circuit of a varactor unit are illustrated below. Based on FIG. 4, an example of each TSV structure of the varactor unit including a corresponding conductor and an insulation layer surrounding the corresponding conductor is described.

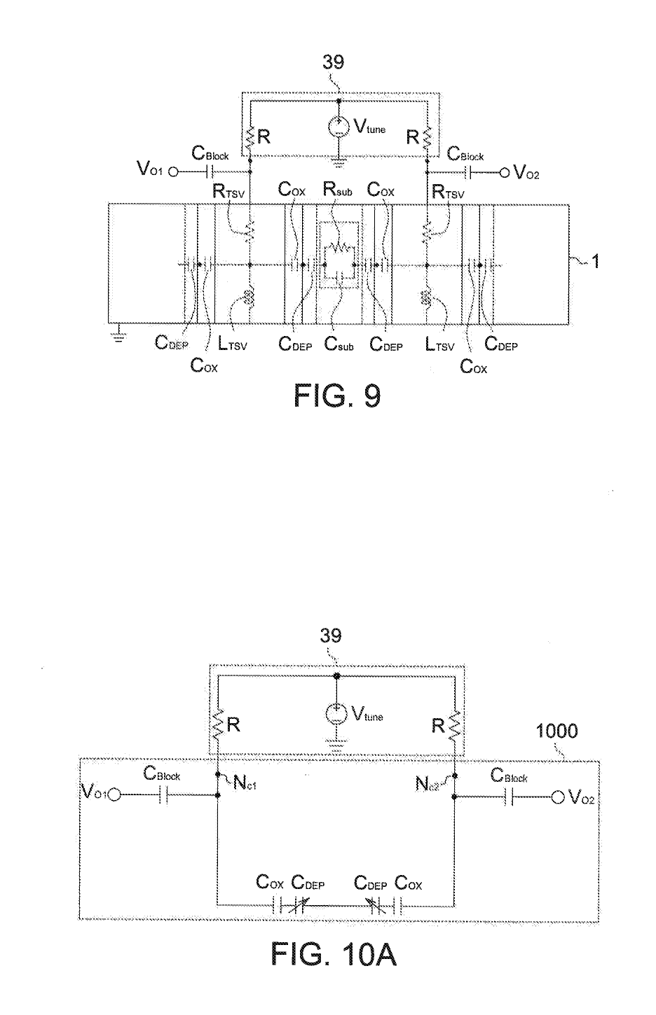

FIG. 9 shows a schematic diagram of an equivalent circuit of the varactor 100 in FIG. 4. Referring to FIG. 9, a depletion region capacitor is denoted as C_{DEP}, an insulation layer capacitor (e.g., an oxidation layer capacitor) is denoted as C_{OX}, and a capacitance value of a DC isolation device is denoted as C_{Block}. In addition to parasitic capacitance of the TSVs, the equivalent circuit of the varactor 110 formed by two TSVs also includes resistivity (R_{TSV}), inductance loss (L_{TSV}) and loss effects (R_{sub} and C_{sub}) of the substrate.

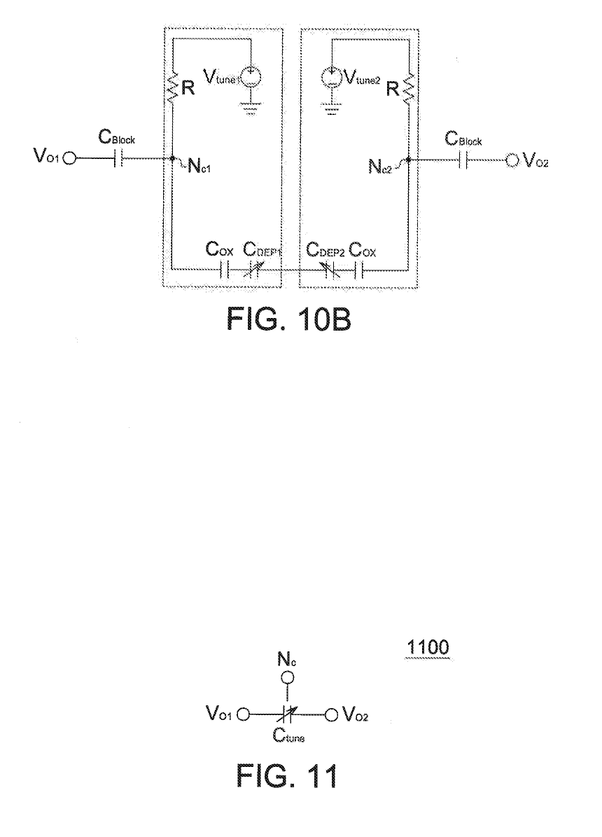

As R_{TSV}, L_{TSV}, R_{sub} and C_{sub} are small in comparison to the parasitic capacitance between the TSVs, influences thereof can be omitted to simplify the equivalent circuit. Hence, the equivalent circuit of the varactor unit 100 is simplified as an equivalent circuit 1000 in FIG. 10A. That is, it is considered that the capacitance value of the varactor 110 is determined by the depletion region capacitor C_{DEP} and the insulation layer capacitor C_{OX}, with the depletion region capacitor C_{DEP} being influenced by bias such that the effective capacitance value of the varactor 110 can be changed. As such, the varactor 100 can be represented by a simplified equivalent circuit 1100 in FIG. 11, wherein Cₜᵤₙₑ represents the equivalent capacitance value of the varactor unit 100, and V_{O1} and V_{O2} represent two end points of the varactor unit 100.

In FIG. 11, the control terminal N_{c} represents a biased end point of the varactor unit 100 for controlling the equivalent capacitance value Cₜᵤₙₑ of the varactor unit 100. In addition to biasing the varactor 100 by utilizing a single voltage, the bias may be independently controlled through two (e.g., the control terminals N_{c1} and N_{c2}) or multiple control terminals in another embodiment, as to be illustrated with reference to FIG. 10B. That is, instead of biasing the control terminals N_{c1} and N_{c} by Vₜᵤₙₑ in a centralized manner, the depletion region capacitors at two left and right sides may be respectively controlled by biasing the control terminal N_{c1} with a bias source Vₜᵤₙₑ₁ and by biasing the control terminal N_{c2} with another bias source Vₜᵤₙₑ₂, where Vₜᵤₙₑ₁ and Vₜᵤₙₑ₂ are in different bias values. At this point, the depletion region capacitor C_{DEP} may be divided into C_{DEP1} and C_{DEP2}, with capacitance values thereof respectively controlled by the bias sources Vₜᵤₙₑ₁ and Vₜᵤₙₑ₂. Therefore, in addition to the foregoing example, the control terminal N_{c} in FIG. 1 may also represent two or more control terminals as end points for biasing the varactor 100. Further, in an embodiment where a varactor unit having multiple pairs of TSVs serves as a varactor, each pair of or particular TSVs may correspond to different bias values. Alternatively, different bias methods maybe simultaneously employed for a varactor unit formed by multi-layer TSVs in another embodiment. The substrate (e.g., the substrate 1) of the varactor unit may be connected to a predetermined voltage level, e.g., a ground level or other voltage levels. Thus, in addition to the above example (e.g., connecting the varactor unit to the bias circuit 39 or the method for biasing the varactor unit), the varactor unit of the embodiment in FIG. 11 in equivalence covers all varactor architectures based on two TSVs.

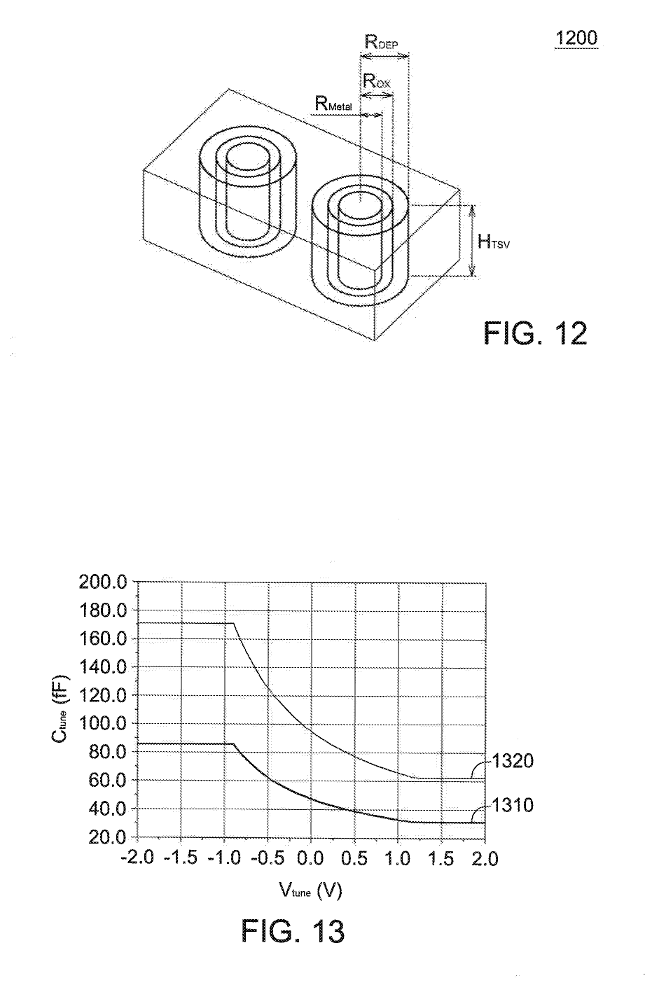

A relationship between the equivalent capacitance value of a varactor formed based on TSVs and a bias change is exemplified below. For example, two cylindrical TSV structures of a varactor 1200 in FIG. 12 have parameters as listed in Table-1.

TABLE 1

| Item | Variable | Default value |
|---|---|---|
| Height of TSV | H_{TSV} | 60 um |
| Thickness of SiO₂ | t_{OX} | 1.1 um |
| Thickness of depletion region | t_{DEP} | Changes with applied |
| | | external voltage |
| Radius of metal | R_{Metal} | 13.9 um |
| Radius of metal including SiO₂ | R_{OX} | 15.0 um |
| Radius of metal including SiO₂ | R_{DEP} | Changes with applied |
| and depletion region | | external voltage |
| Doping concentration of | Nₐ | 1E16 cm⁻³ |
| silicon substrate | | |

Curves in FIG. 13 are obtained from simulations carried out based on the parameters in Table-1. As shown by a curve 1310 in FIG. 13, when the external voltage Vₜᵤₙₑ changes from −0.9V to 1.2V, the varactor capacitance value Cₜᵤₙₑ also changes from 85.5 fF to 31.4 fF, with a maximum being almost 2.7 times of a minimum. As shown by a curve 1320, with the same external voltage change on a two-layer varactor formed based on TSVs (as the varactor unit shown in FIG. 6), the varactor capacitance value Cₜᵤₙₑ also changes from 171 fF to 62.8 fF. Comparing the two examples above, the capacitance value of the two-layer varactor is twice of that of the single-layer varactor.

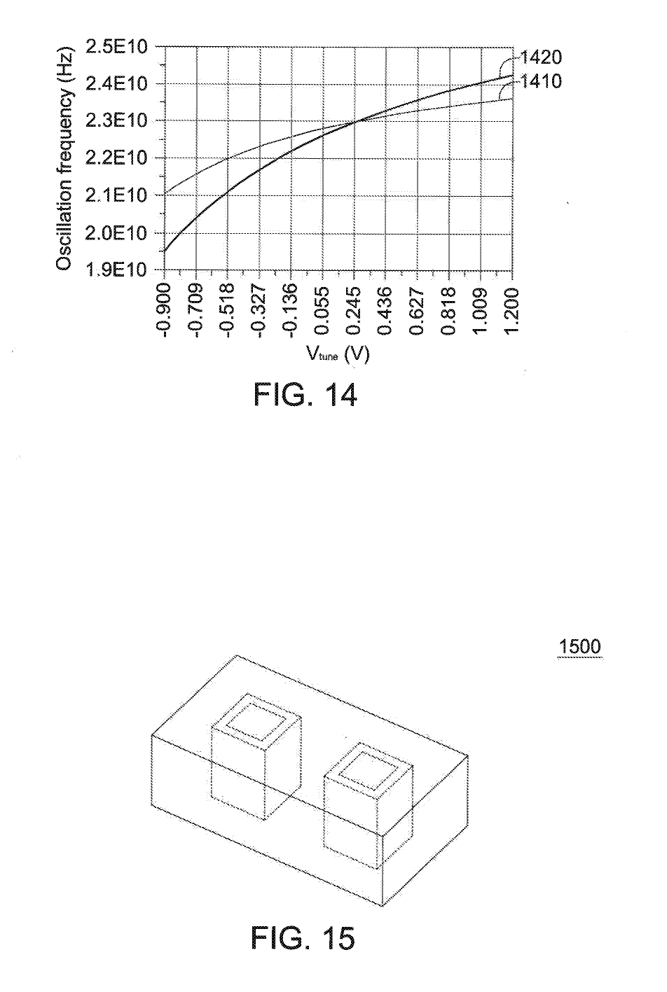

FIG. 14 shows an example of comparing tunable frequency ranges of a VCO having a varactor based on single-layer TSVs and a VCO having a varactor based on two-layer TSVs. As shown by a curve 1410, when the external voltage Vₜᵤₙₑ changes from −0.9V to 1.2V, a frequency change range of the VCO having the single-layer TSV varactor is 21.07 GHz to 23.61 GHz (11.4%). As shown by a curve 1420, a frequency change range of the VCO having the two-layer TSV varactor is 19.54 GHz to 24.25 GHz (21.5%). In this example, the stacked n-layer varactor is capable of achieving an effect of n times of a single-layer TVS varactor, and the VCO accordingly achieves a greater tunable frequency range, where n is an integer greater than or equal to 2.

The varactor unit in the VCO in the foregoing embodiments may be implemented by TSVs and a re-distributed layer (RDL) in a back-end manufacturing process to efficiently utilize an area of the back-end manufacturing process. Further, in the varactor unit, the active element of a front-end manufacturing process may be first implemented by the back-end manufacturing process and then connected by the TSVs, thereby saving an area of the more costly front-end manufacturing process for reduced costs. The varactor architecture formed based on at least two TSVs may also be applied to arrange varactors in multi-layer stacking of a three-dimensional integrated circuit (3D IC) and/or between any desired layers.

The TSV structures of the varactor in the varactor unit may also be implemented by any geometric shapes of TSVs, e.g., cylindrical, ellipsoidal columnar, or other geometrical shapes. For example, a difference of rectangular columnar TSV structures in a varactor 1500 in FIG. 15 from a cylindrical TSV structures is a change in the size of the capacitance value. As a greater and closer equivalent coupling plane exists between two rectangular (e.g., square) TSV structures, a greater capacitance value is generated to be also suitable for serving for a TSV varactor.

In an alternative embodiment, a semiconductor region, such as a well region or a diffusion region, may also be formed outside the insulation layer surrounding the conductor to obtain a varactor unit different from the foregoing varactor unit based on the TSVs.

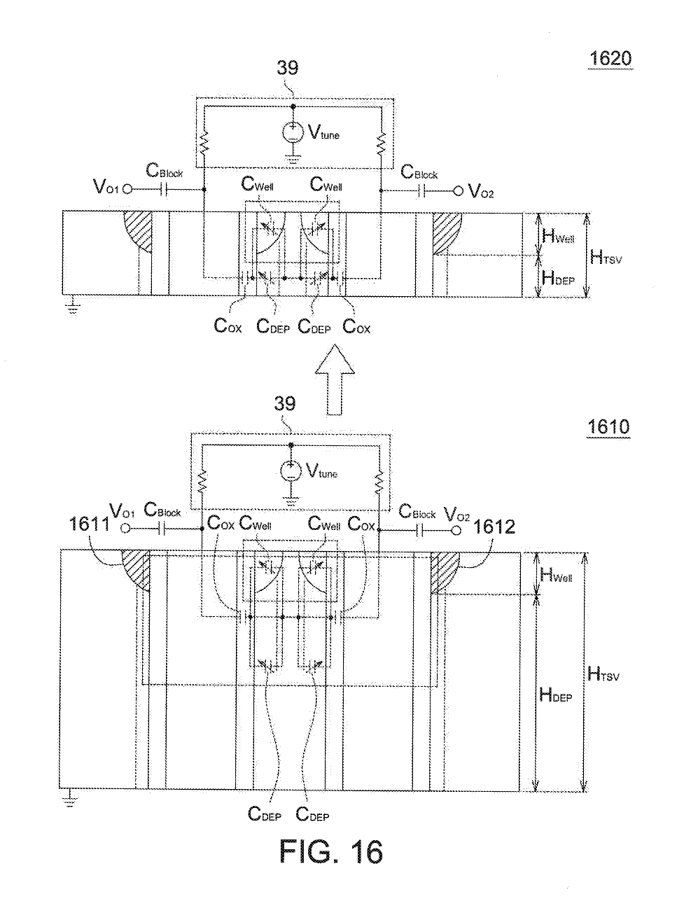

Referring to a varactor unit 1610 in FIG. 16, by taking N+ doped wells 1611 and 1612 for example, when the TSVs are biased, differently-sized depletion regions are incurred in the well regions due to a greater number of carrier electrons and a smaller number of carrier holes. Thus, a corresponding equivalent capacitor C_{Well} is also biased by the TSVs to change the capacitance value. Therefore, in addition to the varactor C_{DEP} of the depletion regions of the TSVs, the equivalent circuit of the varactor unit of the embodiments further includes the varactor C_{Well} of the well regions of the TSVs, with C_{DEP} and C_{Well} in a parallel connection further connected to the insulation layer capacitor C_{OX} in series. According to the principle in FIG. 16, with the TSV structures forming the diffusion region outside the insulation layer, a varactor C_{Diff} for tuning the capacitance value may also be similarly obtained due to the bias of the TSVs.

As a varactor unit 1620 shown in FIG. 16, by implementing a varactor through a smaller TSV height H_{TSV} with a more advanced manufacturing process, a capacitance effect of C_{Well} (or C_{Diff}) becomes even more remarkable comparing a height H_{Well} of the well regions (or the diffusion regions) and a height H_{DEP} of the depletion regions. The method for independently biasing the well regions (or the diffusion regions) may be performed in a centralized manner, or may be performed according to different bias methods in FIG. 10B.

Therefore, the method for implementing the varactor unit is not limited to the methods disclosed in the above embodiments. A circuit architecture including a varactor formed based on at least two TSVs and having at least one control terminal for adjusting a capacitance value of the varactor can be regarded as an embodiment of the varactor unit.

In the above embodiments, two end points of the varactor unit are utilized as the output ends V_{O1} and V_{O2} of the VCO for illustration purposes rather than a limitation to the disclosure. In an alternative embodiment, the VCO may be formed by one or multiple varactors, transistors and other circuit components such as inductors, and may utilize one end of the varactor unit and one end point of a non-varactor unit, or merely end points of a non-varactor unit, as output ends of the VCO.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A voltage-controlled oscillator (VCO), comprising:
an oscillator unit, disposed on a substrate; and
a varactor unit, coupled to the oscillator unit to form a VCO loop, comprising:
a varactor, comprising at least a first through-silicon via (TSV) structure and a second TSV structure, being disposed in the substrate; and
at least one control terminal, coupled to the varactor, for biasing the varactor unit to change a capacitance value of the varactor.

2. The VCO according to claim 1, wherein the at least one control terminal comprises a first control terminal and a second control terminal; the varactor is coupled between the first control terminal and the second control terminal, and changes the capacitance value of the varactor by being biased through the first control terminal and the second control terminal.

3. The VCO according to claim 2, wherein the first TSV structure is coupled to the first control terminal, and the second TSV structure is coupled to the second control terminal.

4. The VCO according to claim 2, wherein the varactor unit further comprises:
at least one first conductive layer, disposed on the substrate, coupled between the first control terminal and the first TSV structure; and
at least one second conductive layer, disposed on the substrate, coupled between the second control terminal and the second TSV structure.

5. The VCO according to claim 1, wherein the VCO further comprises a first output end and a second output end; the varactor unit further comprises:
a first DC isolation device, coupled between the first output end and the varactor; and
a second DC isolation device, coupled between the second output end and the varactor.

6. The VCO according to claim 5, wherein the first DC isolation device and the second DC isolation device are disposed at a same side of the substrate.

7. The VCO according to claim 5, wherein the first DC isolation device and the second DC isolation device are disposed at different sides of the substrate.

8. The VCO according to claim 5, wherein the first DC isolation device comprises at least two correspondingly disposed conductors to render the first DC isolation device to be capacitive, and the second DC isolation device comprises at least two correspondingly disposed conductors to render the second DC isolation device to be capacitive.

9. The VCO according to claim 1, wherein the varactor disposed at the substrate is a first varactor disposed in a first stacked layer; the varactor unit further comprises:
a second varactor, comprising at least a third TSV structure and a fourth TSV structure, disposed in a second stacked layer, coupled to the first varactor.

10. The VCO according to claim 9, wherein the varactor unit further comprises:
a first connecting conductive layer, disposed between the first stacked layer and the second stacked layer, coupled to the first varactor and the second varactor.

11. The VCO according to claim 10, wherein the varactor unit further comprises:
a second connecting conductive layer, disposed between the first stacked layer and the second stacked layer;
wherein the first varactor and the second varactor are connected in parallel via the first connecting conductive layer and the second connecting conductive layer.

12. The VCO according to claim 9, wherein the VCO further comprises a first output end and a second output end; the varactor unit further comprises:
a first DC isolation device, coupled between the first output end and the varactor; and
a second DC isolation device, coupled between the second output end and the varactor.

13. The VCO according to claim 12, wherein the first DC isolation device and the second DC isolation device are disposed on the first stacked layer.

14. The VCO according to claim 12, wherein the first DC isolation device is disposed on the first stacked layer, and the second DC isolation device is disposed on the second stacked layer.

15. The VCO according to claim 1, wherein each of the TSV structures of the varactor unit comprises:
a conductor corresponding to the TSV structure; and
an insulation layer surrounding the corresponding conductor.

16. The VCO according to claim 15, wherein each of the at least two TSV structures of the varactor unit further comprises a semiconductor region surrounding the corresponding insulation layer.

17. The VCO according to claim 16, wherein the semiconductor region provides additional bias to the varactor unit to change the capacitance value of the varactor.

18. The VCO according to claim 1, wherein the oscillator unit comprises;
an active unit; and
an inductor unit.

19. The VCO according to claim 18, wherein the oscillator unit further comprises a capacitor unit.

20. The VCO according to claim 18, wherein the active unit comprises a negative impedance circuit.

21. The VCO according to claim 20, wherein the active unit comprises a cross-coupled transistor pair.

22. The VCO according to claim 1, wherein the oscillator unit comprises an oscillator circuit having a constant oscillation output frequency, and the oscillator unit is coupled to the varactor unit to change a tunable range of the oscillation frequency of the VCO.

23. A VCO circuit, comprising:
an active unit;
an inductor unit; and
a varactor unit, coupled to the active unit and the inductor unit to form a VCO loop, comprising;
a varactor, comprising at least a first TSV structure and a second TSV structure; and
at least one control terminal, coupled to the varactor, for biasing the varactor unit to change a capacitance value of the varactor.

24. A VCO circuit according to claim 23, wherein the at least one control terminal comprises a first control terminal and a second control terminal; the varactor is coupled between the first control terminal and the second control terminal, and changes the capacitance value of the varactor by being biased through the first control terminal and the second control terminal.

25. A VCO circuit according to claim 23, wherein the varactor comprises:
a first depletion region capacitor and a first insulation layer capacitor corresponding to the first TSV structure; and
a second depletion region capacitor and a second insulation layer capacitor corresponding to the second TSV structure;
wherein the first insulation layer capacitor is coupled to the first depletion region capacitor, the second depletion region capacitor is coupled to the second insulation layer capacitor, and the first depletion region capacitor is coupled to the second depletion region capacitor.

26. A VCO circuit according to claim 25, wherein the at least one control terminal comprises a first control terminal and a second control terminal; the varactor is coupled between the first control terminal and the second control terminal, and changes capacitance values of the first depletion region capacitor and the second depletion region capacitor by being biased via the first control terminal and the second control terminal, respectively.

27. A VCO circuit according to claim 25, wherein the varactor further comprises:
a first semiconductor region capacitor corresponding to the first TSV structure; and
a second semiconductor region capacitor corresponding to the second TSV structure;
wherein the first semiconductor region capacitor is connected to the first depletion region capacitor in parallel, and the second semiconductor region capacitor is connected to the second depletion region capacitor in parallel.

28. A VCO circuit according to claim 23, wherein the VCO further comprises a first output end and a second output end; and the varactor unit further comprises:
a first DC isolation capacitor, coupled between the first output end and the varactor; and
a second DC isolation capacitor, coupled between the second output end and the varactor.

29. A VCO circuit according to claim 28, wherein the varactor is a first varactor; the varactor unit further comprises:
a second varactor, coupled to the first varactor, comprising at least a third TSV structure and a fourth TSV structure.

30. A VCO circuit according to claim 23, wherein the varactor is a first varactor; the varactor unit further comprises:
a second varactor, coupled to the first varactor, comprising at least a third TSV structure and a fourth TSV structure.

31. A VCO circuit according to claim 23, wherein the active unit comprises a negative impedance circuit.
